(19) United States
(12) Patent Application Publication
(10) Pub. No.: US 2009/0315455 A1
(43) Pub. Date: Dec. 24, 2009

(54) Oled Display Device and Method for Fabricating Same

(75) Inventors: Shih-Chang Wang, Miao-Li (TW); Hong-Gi Wu, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/456,751

(22) Filed: Jun. 22, 2009

(30) Foreign Application Priority Data
Jun. 20, 2008 (CN) 2008 10067936.0

(51) Int. Cl. H01L 51/50; H01L 51/56; H01L 51/30

(52) U.S. Cl. 313/504; 438/29; 257/40; 257/E21.411; 257/E51.041

(57) ABSTRACT

An organic light emitting diode (OLED) display device includes a substrate and an organic thin film transistor (OTFT) on the substrate. The OTFT includes a gate, an insulating layer covering the gate, and a channel layer arranged on the insulating layer corresponding to the gate. The channel layer includes a doped layer. A method for fabricating the OLED display device is also provided.

### BACKGROUND

1. Technical Field

The present disclosure relates to organic light emitting diode (OLED) display devices, and particularly to an OLED display device with an organic thin film transistor having a doped layer in a channel layer and a method for fabricating the OLED display device.

2. Description of Related Art

Organic light emitting diodes (OLEDs) are electroluminescent (EL) devices that have one or more organic EL layers. An OLED emits light generated by radiative recombination of injected electrons and holes within the organic EL layers. OLEDs have electrical and optical characteristics which are attractive for operation within pixel-addressed displays. For example, OLEDs operate at low voltages and are relatively efficient. In addition, OLEDs can be fabricated into thin, lightweight display devices, which are called OLED display devices. Furthermore, OLEDs can be designed to emit light of different colors to create color display devices. Therefore, OLED display devices are becoming more and more popular.

In a conventional OLED display device, the OLED in the OLED display device is controlled by a switch element, such as an organic thin film transistor (OTFT). The OTFT usually includes an organic channel layer to transport electricity. However, when the OTFT is switched off, some negative electric charge remains in the organic channel layer. This results in a leakage current in the organic channel layer. Thus the OTFT cannot be switched off completely. The leakage current is liable to cause an image displayed by the OLED display device to be unstable.

Therefore, an OLED display device that can overcome the above deficiencies is needed.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views, and all the views are schematic.

FIG. 1 is a circuit diagram of one pixel unit of an OLED display device of an exemplary embodiment of the present disclosure.

FIG. 2 is a cross-sectional view of one pixel unit of the OLED display device of the first embodiment, the view corresponding to the diagram of FIG. 1.

FIG. 3 is a flow chat summarizing a method for fabricating the OLED display device of the first embodiment.

FIGS. 4-15 are cross-sectional views corresponding to FIG. 2, and illustrating sequential stages in the method of FIG. 3.

### DETAILED DESCRIPTION

Reference will now be made to the drawings to describe various embodiments in detail.

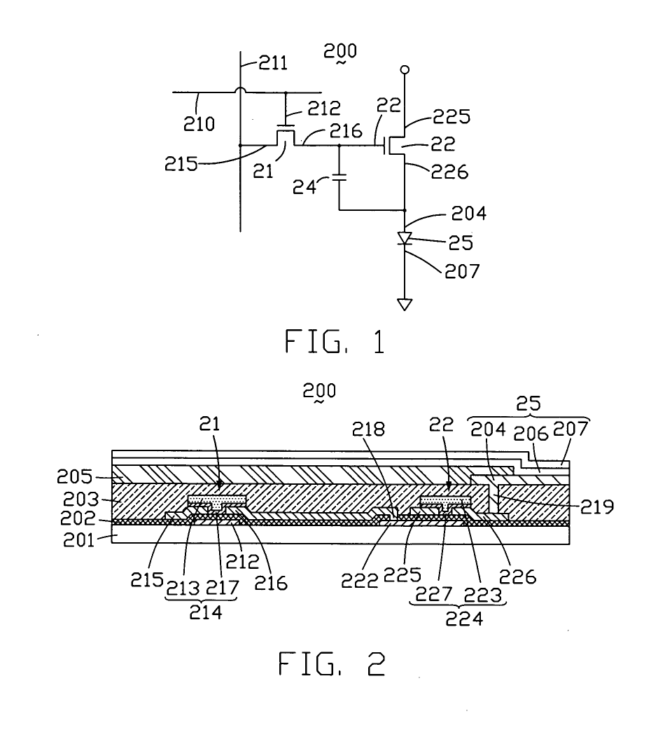

Referring to FIG. 1, this is a circuit diagram of one pixel unit of an organic light emitting diode (OLED) display device according to an exemplary embodiment of the present disclosure. The OLED display device 200 includes a plurality of such pixel units arranged in a regular array. Each pixel unit includes a scan line 210, a data line 211 crossing the scan line 210, a first organic thin film transistor (OTFT) 21, a second OTFT 22, a storage capacitor 24, and an OLED 25. The first OTFT 21 and second OTFT 22 are positioned at the intersection of the data line 211 and the scan line 210. The first OTFT 22 includes a first source 215, a first gate 212, and a first drain 216. The first source 215 is electrically connected to the data line 211 for receiving data signals therefrom. The first gate 212 is electrically connected to the scan line 210 for receiving scanning signals therefrom. The first drain 216 is electrically connected to one electrode of the storage capacitor 24. The second OTFT 22 includes a second source 225, a second gate 222, and a second drain 226. The second source 225 is electrically connected to a power source (not labeled). The second gate 222 is electrically connected to the first drain 216 of the first OTFT 21. The second drain 226 is electrically connected to an anode 204 of the OLED 25 and the other electrode of the storage capacitor 24. The storage capacitor 24 is used to store data signals. A cathode 207 of the OLED 25 is grounded.

Referring to FIG. 2, this is an enlarged cross-sectional view of the pixel unit of the OLED display of FIG. 1. The OLED display 200 further includes a substrate 201. The substrate 201 can, for example, be a glass substrate or a flexible transparent substrate that is flexible. The scan line 210, the data lines211, the first OTFT 21, the second OTFT 22, the storage capacitor 24, and the OLED 25 are arranged on the substrate 201.

In detail, the scan line 210 and the first and second gates 212, 222 of the first and second OTFTs 21, 22 are directly formed on the substrate 201. A first insulating layer 202, which can be made of silicon nitride (SiₓN_{y}), is formed covering the scan line 210 and the first and second gates 212, 222. The form of silicon nitride can for example be Si₃N₄, Si₂N₃, etc. Each of the first and second gates 212, 222 can be considered to have two sides. The first source 215 and first drain 216 of the first OTFT 21 are formed on the two sides of the first gate 212. The first drain 216 is long and is electrically connected to the second gate 222 of the second OTFT 22 via a first connecting hole 218 formed in the first insulating layer 202. The second source 225 and second drain 226 of the second OTFT 22 are formed on the two sides of the second gate 222. A first p-doped organic layer 217 is formed on the first source 215 and the first drain 216, corresponding to the first gate 212. A first active layer 213 is formed on the first p-doped organic layer 217. The first p-doped organic layer 217 and the first active layer 213 cooperatively define a first channel layer 214. A second p-doped organic layer 227 is formed on the second source 225 and the second drain 226, corresponding to the second gate 222. A second active layer 223 is formed on the second p-doped organic layer 227. The second p-doped organic layer 227 and the second active layer 223 cooperatively define a second channel layer 224.

A passivation layer 203 is formed covering the first and second sources 215, 225, the first and second channel layers 214, 224, the first and second drains 216, 226, and the first insulating layer 202. A second connecting hole 219 is formed in the passivation layer 203 corresponding the second drain 226, thereby providing access to the second drain 226. The anode 204 of the OLED 25 is formed on the passivation layer 203 and is electrically connected to the drain 226 of the second TFT 22 via the second connecting hole 219. A second insulating layer 205 is formed on the passivation layer 203, covering a portion of the anode 204 of the OLED 25. An organic light emitting layer 206 and the cathode 207 of the OLED 25 are sequentially formed on the second insulating layer 205. The anode 204, the organic emitting layer 206, and the cathode 207 cooperatively define the OLED 25.

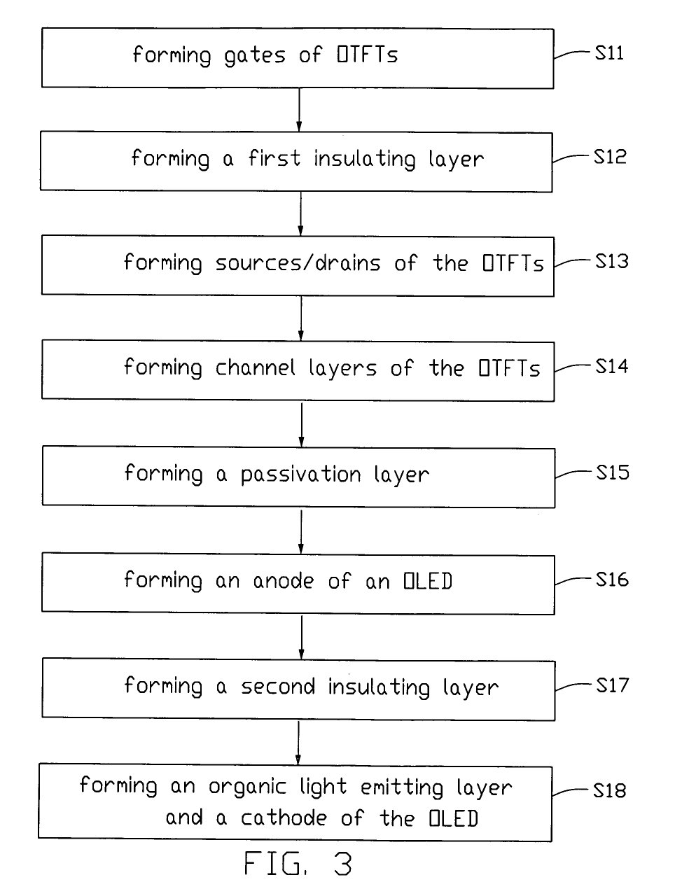

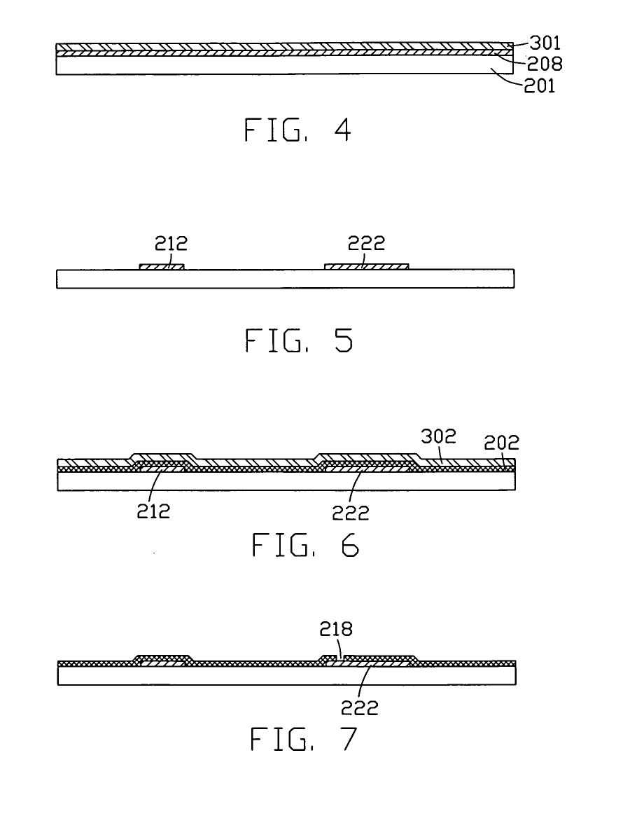

Referring to FIG. 3, this is a flow chart summarizing an exemplary method for fabricating the OLED display device 200. The method includes the following steps described in relation to one pixel unit only: step S11, forming gates of OTFTs; step S12, forming a first insulating layer; step S13, forming sources/drains of the OTFTs; step S14, forming p-doped layers and active layers (i.e., forming channel layers) of the OTFTs; step S15, forming a passivation layer; step S16, forming an anode of an OLED; step S17, forming a second insulating layer 205; and step S18, forming an organic light emitting layer and a cathode of the OLED. The method is detailed below with reference to FIGS. 4-15, which are cross-sectional views illustrating sequential stages in the method.

In step S11, referring to FIG. 4, a substrate 201 is firstly provided. A first metal layer 208 and a first photoresist layer 301 are sequentially formed on the substrate 201. The first metal layer 208 can be a single layer or multi-layer structure. The first metal layer 208 preferably includes aluminum (Al), molybdenum (Mo), chromium (Cr), tantalum (Ta), or copper (Cu), or a suitable combination of any of these metals, and is for example formed by physical vapor deposition (PVD). An exemplary thickness of the first metal layer 208 is about 300 nm.

Also referring to FIG. 5, a first photolithography and etching process (PEP) is performed to form a first gate 212 and a second gate 222. Then the first photoresist layer 301 is removed.

In step S12, referring to FIG. 6, a first insulating layer 202 and a second photoresist layer 302 are sequentially formed on the substrate 201, covering the first and second gates 212, 222. The first insulating layer 202 preferably includes SiₓN_{y}, and is for example formed by chemical vapor deposition (CVD). SiₓN_{y} can for example be Si₃N₄, Si₂N₃, etc. Then, a second PEP is performed to form a first connecting hole 218. After that, the second photoresist layer 302 is removed.

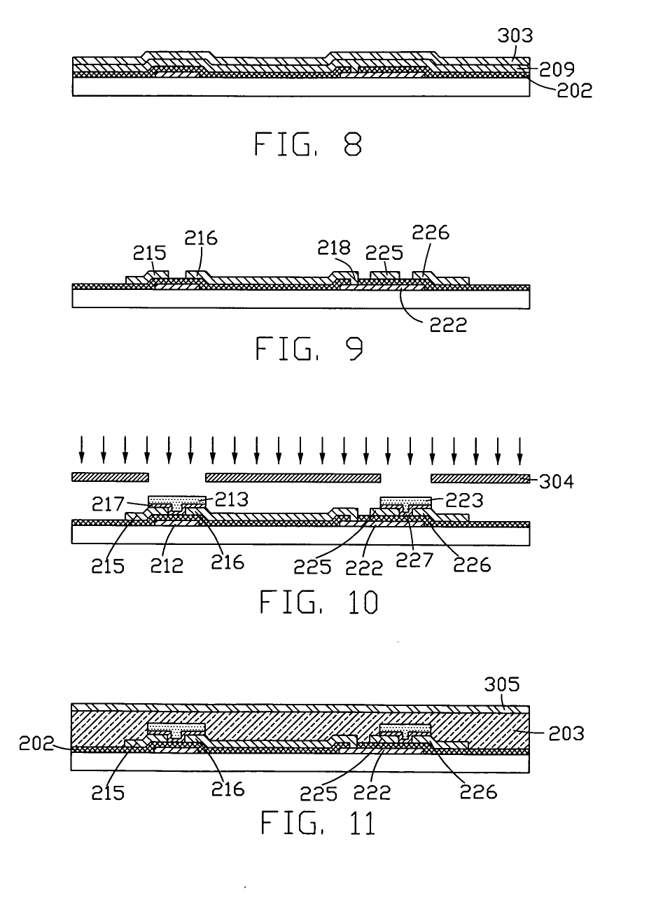

In step S13, referring to FIG. 8, a second metal layer 209 and a third photoresist layer 303 are sequentially formed on the second insulating layer 202. The second metal layer 209 preferably includes Mo alloy or Cr, and is for example formed by PVD. An exemplary thickness of the second metal layer 209 is about 200 nm.

Also referring to FIG. 9, a third PEP is performed to form a first source 215, a first drain 216, a second source 225, and a second drain 226. The first drain 216 is electrically connected to the second gate 222 via the first connecting hole 218. Then the third photoresist layer 303 is removed.

In step S14, referring to FIG. 10, a thermal evaporation process is performed, with a mask 304, to form a first p-doped layer 217 and a first active layer 213 sequentially on the first source 215 and the first drain 216 corresponding to the first gate 212, and form a second p-doped layer 227 and a second active layer 223 sequentially on the second source 225 and the second drain 226 corresponding to the second gate 222. The first and second p-doped layers 217, 227 are made of organic polymer with p-type dopant. The organic polymer can, for example, be pentacene or poly-3-hexylthiophene. The dopant can, for example, be tungsten trioxide (WO₃) or 2,3,5,6-tetrafluoro-7,7,8,8-tetracyanoquinodimethane. The first and second active layers 213, 223 are made of organic polymer, which can, for example, be pentacene or poly-3-hexylthiophene. The first p-doped layer 217 and the first active layer 213 cooperatively define a first channel layer 214. The second p-doped layer 227 and the second active layer 223 cooperatively define a second channel layer 224.

In step S15, referring to FIG. 11, a passivation layer 203 and a fourth photoresist layer 305 are sequentially formed on the substrate 201, covering the first and second sources 215, 225, the first and second drains 216, 226, the first and second active layers 213, 223, and the first insulating layer 202. The passivation layer 203 preferably includes SiₓN_{y}, and is for example formed by CVD. SiₓN_{y} can for example be Si₃N₄, Si₂N₃, etc. Then, a fourth PEP is performed to form a second connecting hole 219, as shown in FIG. 12. Then the fourth photoresist layer 305 is removed.

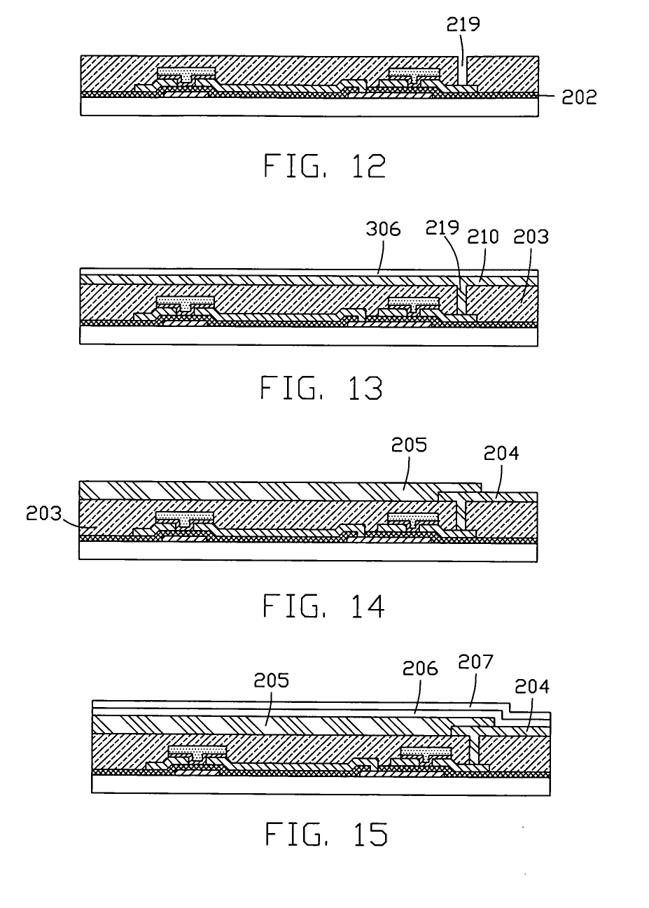

In step S16, referring to FIG. 13, a third metal layer 210 and a fifth photoresist layer 306 are sequentially formed on the passivation layer 203, with the second connecting hole 219 filled with the third metal layer 210. The third metal layer 210 can, for example, be made of indium tin oxide (ITO) or indium zinc oxide (IZO), and can, for example, be formed by PVD.

Also referring to FIG. 14, a fifth PEP is performed to form an anode 204, which is electrically connected to the second drain 226. Then the fifth photoresist layer 305 is removed. After that, a second insulating layer 205 is formed on the passivation layer 203, covering a portion of the anode 204.

In step S17, an organic emitting layer 206 and a cathode 207 are sequentially formed on the second insulating layer 205 and the anode 204. The cathode 207 is transparent, and can, for example, be made of ITO or IZO by PVD.

Unlike with a conventional OLED display, each of the first and second channel layers 214, 224 of the first and second OTFTs 21, 22 includes a p-doped layer 217, 227 and an active layer 213, 223. The dopant in the p-doped layers 217, 227 is tungsten trioxide (WO₃) or 2,3,5,6-tetrafluoro-7,7,8,8-tetracyanoquinodimethane. In operation of the OLED display device 200, when the first and second OTFTs 21, 22 are in an “off” state, the dopant in the first and second p-doped layers 217, 227 provides positive electric charge to counteract negative electric charge in the first and second channel layers 214, 224. Thus a leakage current in the first and second channel layers 214, 224 is reduced or even eliminated. Accordingly, the first and second OTFTs 21, 22 can be switched off completely or substantially completely. Thereby, the stability of images displayed by the OLED display device 200 can be improved.

Furthermore, the dopant in the first and second p-doped layers 217, 227 reduces a contact barrier between the first active layer 213 and the first source/drain 215, 216 of the first OTFT 21, and reduces a contact barrier between the second active layer 223 and the second source/drain 225, 226 of the second OTFT 22. Thus a resistance between the first source 215 and the first drain 216, and a resistance between the second source 225 and the second drain 226, are both reduced. This helps to increase the switching speeds of the first and second OTFTs 21, 22, and thereby improve the display quality of the OLED display device 200.

It is to be understood that even though numerous characteristics and advantages of the present embodiments have been set forth in the foregoing description, with details of the structures and functions of the embodiments, the disclosure is illustrative only; and that changes may be in detail, especially in matters of shape, size, and arrangement of parts, within the principles of the embodiments, to the full extent indicated by the broad general meaning of the terms in which the appended claims are expressed.

What is claimed is:

1. An organic light emitting diode (OLED) display device, comprising:
a substrate; and
at least one organic thin film transistor (OTFT) provided at the substrate, each of the at least one OTFT comprising a gate, an insulating layer covering the gate, and a channel layer arranged on the insulating layer corresponding to the gate, wherein the channel layer comprises a doped layer.

2. The OLED display device of claim 1, wherein the doped layer is a p-type doped layer.

3. The OLED display device of claim 1, wherein dopant in the doped layer is one of tungsten trioxide (WO₃) and 2,3,5,6-tetrafluoro-7,7,8,8-tetracyanoquinodimethane.

4. The OLED display device of claim 1, wherein each of the at least one OTFT further comprises a source and a drain, the source and drain being arranged between the insulating layer and the channel layer.

5. The OLED display device of claim 4, wherein the channel layer further comprises an active layer, the active layer being arranged on the doped layer.

6. The OLED display device of claim 5, wherein the active layer is made of organic polymer.

7. The OLED display device of claim 5, wherein at least one of the doped layer and the active layer is made of a selected one of pentacene and poly-3-hexylthiophene.

8. The OLED display device of claim 1, further comprising a scan line, a data line, an OLED, and a storage capacitor, the at least one OTFT comprising a first OTFT and a second OTFT, the source of the first OTFT being connected to the data line, the gate of the first OTFT being connected to the gate line, the drain of the first OTFT being connected to the gate of the second OTFT, the drain of the second OTFT being connected to the OLED, and the storage capacitor being connected between the drain of the first OTFT and the OLED.

9. A method for fabricating an organic light emitting diode (OLED) display device, the method comprising:
providing a substrate and forming a gate of an organic thin film transistor (OTFT) on the substrate;
forming an insulating layer covering the gate; and
forming a channel layer on the insulating layer corresponding to the gate, the channel layer comprising a doped layer.

10. The method of claim 9, further comprising forming a source and a drain between the insulating layer and the channel layer.

11. The method of claim 10, wherein the channel layer further comprises an active layer on the doped layer, and forming the channel layer comprises forming the doped layer on the insulating layer, and forming the active layer on the doped layer.

12. The method of claim 11, wherein at least one of the doped layer and the active layer is made of a selected one of organic polymer and poly-3-hexylthiophene.

13. The method of claim 9, wherein dopant in the doped layer is one tungsten trioxide (WO₃) and 2,3,5,6-tetrafluoro-7,7,8,8-tetracyanoquinodimethane.

14. The method of claim 9, further comprising forming an OLED on the substrate.

15. An organic thin film transistor (OTFT), comprising:
a gate;
an insulating layer covering the gate;
a source and a drain arranged on the insulating layer; and
an organic channel layer arranged on the source and drain corresponding to the gate, wherein the organic channel layer comprises a doped layer.

16. The OTFT of claim 15, wherein the doped layer is a p-type doped layer.

17. The OTFT of claim 16, wherein dopant in the doped layer is one of tungsten trioxide (WO₃) and 2,3,5,6-tetrafluoro-7,7,8,8-tetracyanoquinodimethane.

18. The OTFT of claim 16, wherein the channel layer further comprises an active layer on the doped layer.

19. The OTFT of claim 18, wherein at least one the doped layer and the active layer is made of a selected one of pentacene and poly-3-hexylthiophene.
